(19) United States
(12) Patent Application Publication
(10) Pub. No.: US 2014/0177873 A1
(43) Pub. Date: Jun. 26, 2014

(54) PORTABLE ELECTRONIC DEVICE WITH COMBINATION BUTTON FOR POWER AND VOLUME AND OPERATING METHOD

(71) Applicants: FIH (HONG KONG) LIMITED, Kowloon (HK); SHENZHEN FUTAIHONG PRECISION INDUSTRY CO., LTD., Shenzhen (CN)

(72) Inventors: CHIH-WEI CHANG, New Taipei (TW); XIAO-SHAN LI, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 14/010,532

(22) Filed: Aug. 27, 2013

(30) Foreign Application Priority Data
Dec. 24, 2012 (CN) 2012105651955

(51) Int. Cl. H03G 3/00

(52) U.S. Cl. CPC H03G 3/00
USPC 381/104

(57) ABSTRACT

A portable electronic device includes a combination button and a gravity sensor. The gravity sensor detects gravity variation of the portable electronic device. When the combination button is pressed for a first predetermined time, the gravity sensor begins. When the combination button is pressed within a second predetermined time and the gravity sensor detects no gravity variation, the combination button's power switch function shuts down the portable electronic device. If the gravity sensor detects a gravity variation, the combination button's volume adjusting function can increase or decrease the volume of the portable electronic device according to the gravity variation.

### BACKGROUND

1. Technical Field

The present disclosure relates to portable electronic devices, and particularly relates to a portable electronic device with a combination button for controlling power and adjusting volume, and an operating method of the portable electronic device.

2. Description of Related Art

Electronic device often have separate power button and volume buttons. The power button and volume buttons are arranged on different sidewalls of a housing of a portable electronic device. More buttons on an electronic device means higher costs of manufacture. Multiple buttons needed also poses as a limit on design of the electronic device.

Therefore, it is desirable to eliminate multiple buttons for both power and volume control.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 illustrates an electronic device with a combination button for power and volume of a preferred embodiment of the present disclosure.

FIG. 2 illustrates a step of a volume adjusting process of the portable electronic device of FIG. 1 in a first embodiment.

FIG. 3 illustrates another step of the volume adjusting process of the portable electronic device of FIG. 1 in the first embodiment.

FIG. 4 illustrates a step of a volume adjusting process of the portable electronic device of FIG. 1 in a second embodiment.

FIG. 5 illustrates another step of the volume adjusting process of the portable electronic device of FIG. 1 in the second embodiment.

FIG. 6 illustrates a flowchart of an operating method of the portable electronic device of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one”.

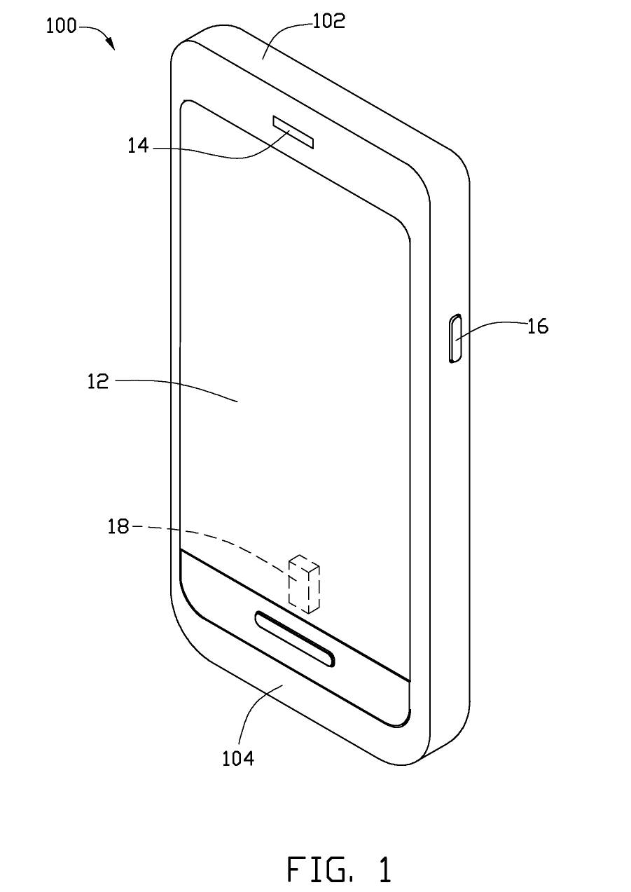

FIG. 1 illustrates a portable electronic device 100 of a preferred embodiment of the present disclosure with a combination button for power and volume. The portable electronic device 100 can be a mobile phone, a tablet computer or a personal digital assistant, for example. In the present embodiment, the portable electronic device 100 is a mobile phone.

The portable electronic device 100 is rectangularly-shaped, and includes a first end 102 and a second end 104 opposite to the first end 102. A display 12 and a receiver 14 are arranged on a front surface of the portable electronic device 100. The display 12 can be a touch screen. The receiver 14 is adjacent to the first end 102 and supplies audio when the portable electronic device 100 is positioned close to an ear of a user. A combination button 16 is arranged on a sidewall of the portable electronic device 100 adjacent to the first end 102. The combination button 16 combines functions of a power switch and a volume adjusting control of the portable electronic device 100. In the present embodiment, the combination button 16 can be an elastic button that, enforces the tactile sensation for the user. The portable electronic device 100 further includes a gravity sensor 18 mounted adjacent to the second end 104. The gravity sensor 18 detects gravity variation of the second end 104.

A volume adjusting process of the portable electronic device 100 is described below. When the portable electronic device 100 is on, the combination button 16 is pressed for a predetermined time T1, and the gravity sensor 18 detects gravity variation of the portable electronic device 100. When the combination button 16 is pressed for another predetermined time T2 without gravity variation detected by the gravity sensor 18, that is to say a present position of the portable electronic device 100 is maintained, the portable electronic device system starts the power switch function to shut down the portable electronic device 100. When the combination button 16 is pressed repeatedly and the gravity sensor 18 detects gravity variation, that is the present position of the portable electronic device 100 changed. The portable electronic device system starts the volume adjusting control function to adjust the volume of the portable electronic device 100.

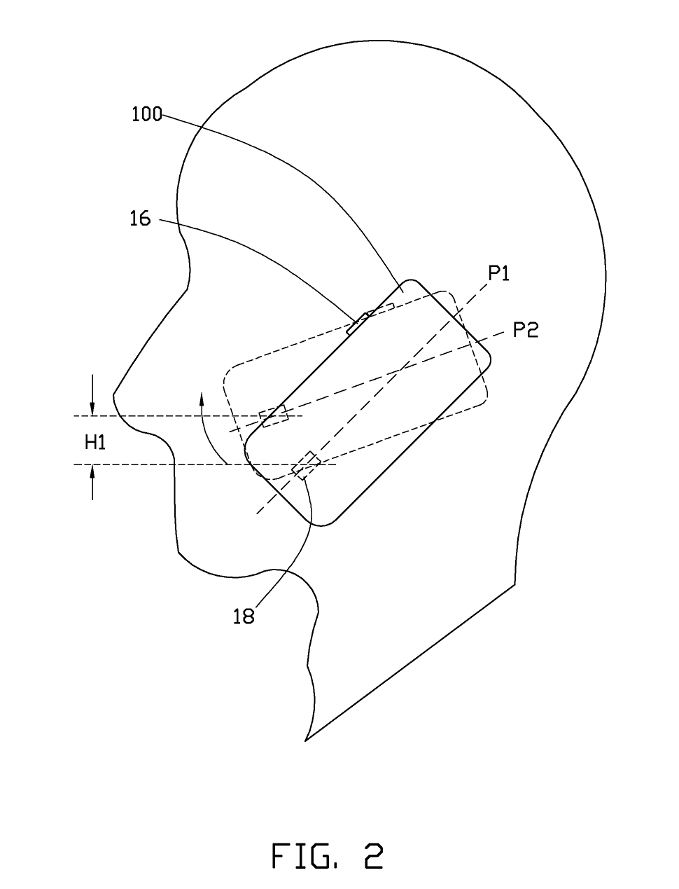

In the embodiment, FIG. 2 shows that the volume adjusting control function of the combination button 16 can include a volume adjusting range. In a first embodiment of the present disclosure, when an user communicates using the portable electronic device 100, the user holds the portable electronic device 100 with the display 12 facing a head of the user with the receiver 14 kept close to an ear of the user, the portable electronic device 100 is located in an initial position P1. The user presses the combination button 16 for the predetermined time T1, and then the portable electronic device system starts the gravity sensor 18. The position that the receiver 14 kept close to the ear acts a first fixed point. If the user rotates the second end 104 of the portable electronic device 100 towards a top of the head to a second position P2. Thus the gravity sensor 18 is moved upward from the initial position P1 to the second position P2, and detects a vertical upward displacement H1 (see FIG. 2), thereby the gravity sensor 18 detects a gravity increment G1. The portable electronic device system increases the volume according to the gravity increment G1 and adjusts the volume increment according to the displacement H1.

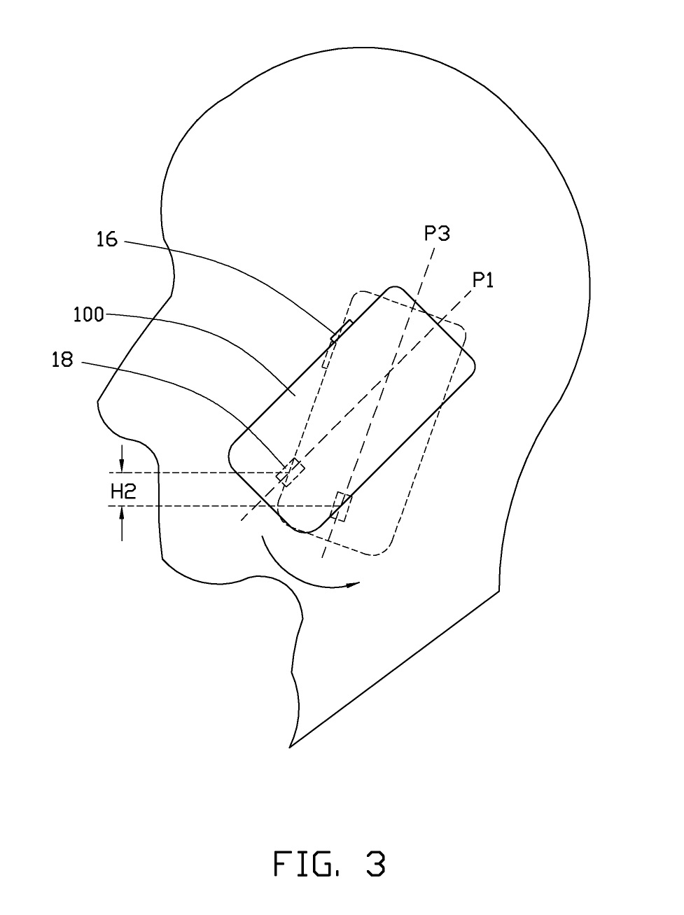

FIG. 3 shows that when the user communicates using the portable electronic device 100, and the portable electronic device 100 is held in the initial position P1. The user presses the combination button 16 for the predetermined time T1, and then the portable electronic device system starts the gravity sensor 18. The position that the receiver 14 is kept close to the ear acts the first fixed point. The user rotates the second end 104 of the portable electronic device 100 towards a neck of the user to a third position P3. Thus the gravity sensor 18 is moved downward from the initial position P1 to the third position P3, and detects a vertical downward displacement H2 (see FIG. 3). Thereby the gravity sensor 18 detects a gravity decrement G2. The portable electronic device system decreases the volume according to the gravity decrement G2 and adjusts the volume decrement according to the displacement H2.

When the user holds the portable electronic device 100 and keeps the receiver 14 close to his/her ear, it is comfortable for the user to keep pressing the combination button 16 and rotate the second end 104 upward or downward, corresponding to human actions.

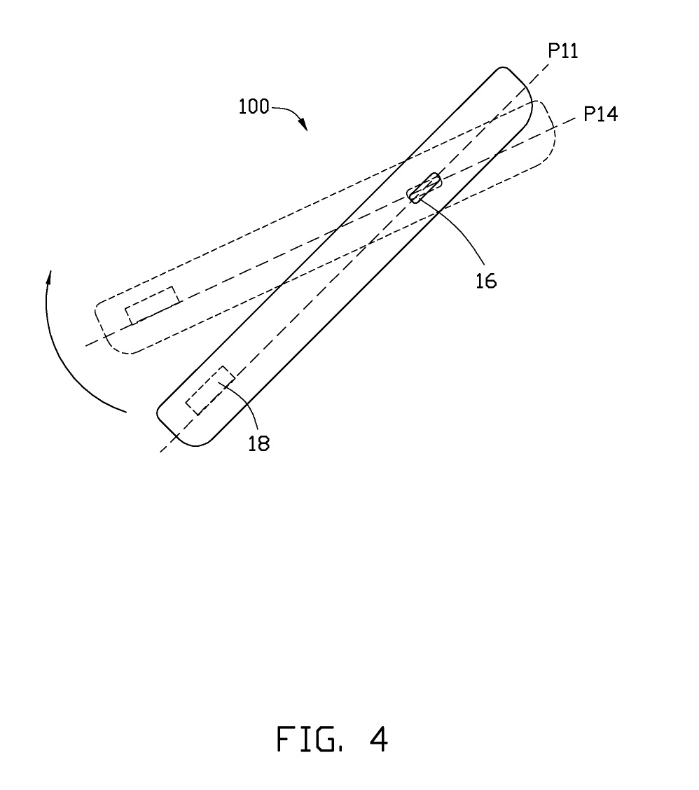

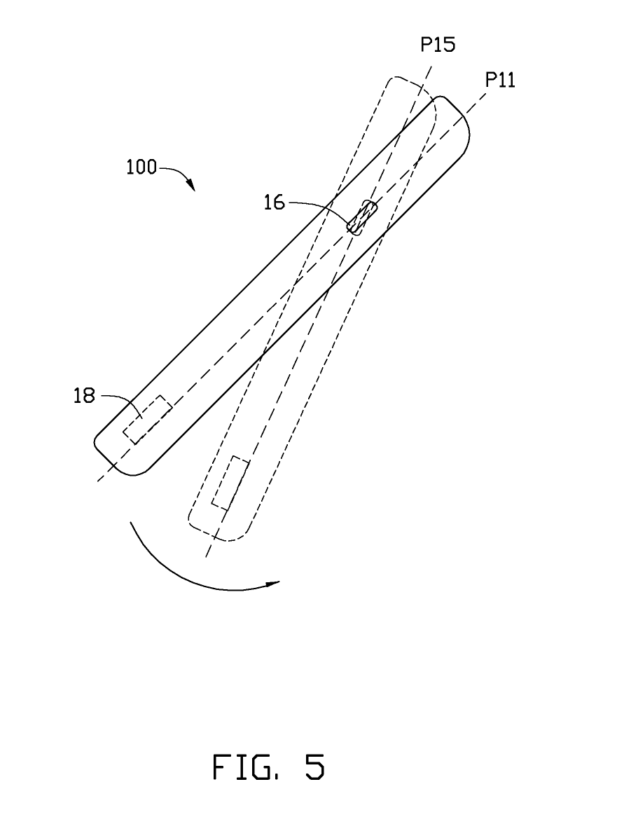

FIG. 4 and FIG. 5 show a second embodiment of the present disclosure, when the user communicates with others using the portable electronic device 100 via a speaker or an earphone, or uses application programs of the portable electronic device 100.

In the second embodiment, the user holds the portable electronic device 100 a predetermined distance from the display 12. The portable electronic device 100 is located in the initial position P11. The user presses the combination button 16 for the predetermined time T1, and then the portable electronic device system starts the gravity sensor 18. The position that the user presses the combination button 16 acts a second fixed point. The user rotates the second end 104 towards or backwards from a fourth position P14 or a fifth position P15. Thus, the gravity sensor 18 is moved from the initial position P1 upward to the fourth position P14 or downward to the fifth position P15, and detects a vertical upward displacement or a vertical downward displacement correspondingly. Thereby the gravity sensor 18 detects a gravity increment or decrement accordingly, and the volume adjusting control function of the combination button 16 is started. The portable electronic device system increases or decreases the volume according to the gravity increment or decrement and adjusts the volume decrement according to the displacement.

When the user uses an application program such a game, the user may press the combination button 16 and rotate the portable electronic device 100 to adjust volume of the application program. Thus the user does not need to pause or quit the application program to adjust the volume.

It is known that the user loosens the combination button 16 to finish the volume adjustment.

When the portable electronic device 100 is powered off, the user can press the combination button 16, which starts the power switch function, to startup the portable electronic device 100.

The user also can preset the gravity sensor 18 according to personal habit, when the gravity sensor 18 detects a gravity increment, triggering decreasing volume; while the gravity sensor 18 detects a gravity decrement, triggering increasing volume.

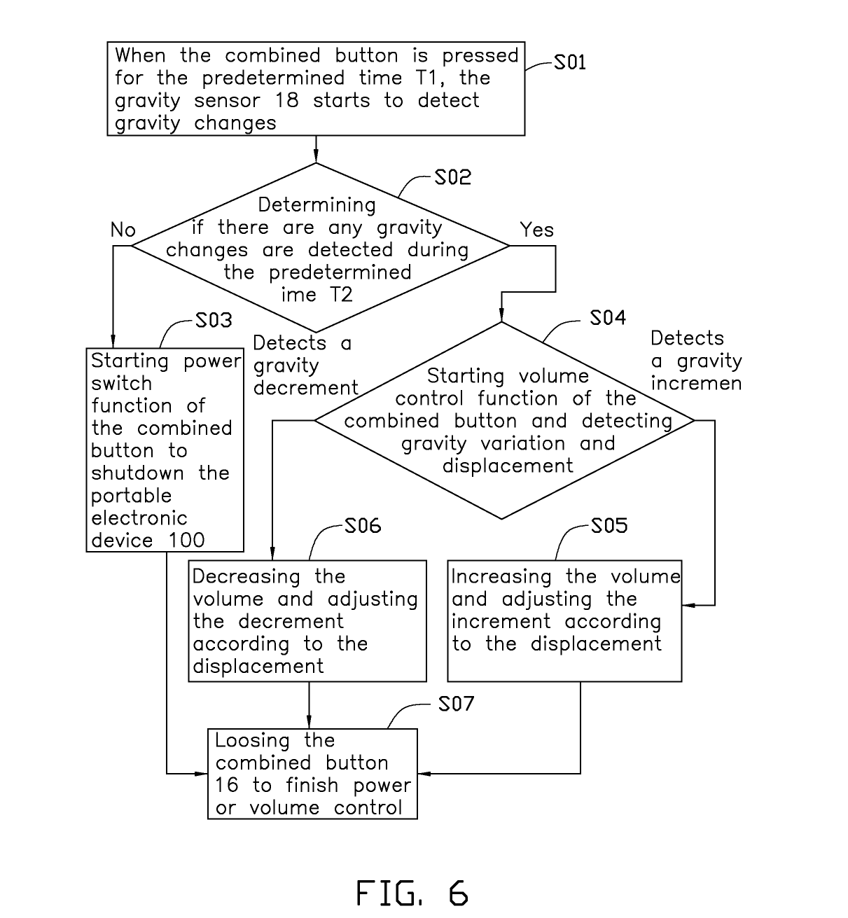

FIG. 6 shows an operating method of the portable electronic device 100 of present embodiment. The operating method includes the following steps:

In step S01, when the combination button is pressed for the predetermined time T1, and then the gravity sensor 18 starts to detect a gravity variation.

In step S02, the gravity sensor 18 determines the gravity variation detected during the predetermined time T2. When the gravity variation is within a first range, step S03 is operated; when the gravity variation is within a second range or within a third range, step S04 is operated.

In step S03, the power switch function of the combination button 16 shuts down the portable electronic device 100. When the detected gravity variation is zero, the detected gravity is within the first range.

In step S04, the volume adjusting control function of the combination button 16 can start to calculate the gravity variation and a displacement.

In step S05, the volume is increased according to the gravity variation. When detecting a gravity increment, the gravity variation is within the second range, the volume is increased. The volume is adjusted according to the displacement.

In step S06, the volume is decreased according to the gravity variation. When detecting a gravity decrement, the gravity variation is within the third range, the volume is decreased. The volume is adjusted according to the displacement.

In step S07, the combination button 16 is released to stop the adjustment of power or volume control.

The portable electronic device 100 of the present disclosure combines the power switch function and volume adjusting control function on a single combination button 16, which can decrease cost of manufacturing. In addition, the combination button 16 allows more design possibilities than multiple buttons that were in prior arts. Furthermore, it is more convenient for the user to press the combination button 16 and rotates the portable electronic device 100 to adjust volume than to press multiple buttons.

Even though numerous characteristics and advantages of the embodiments have been set forth in the foregoing description, together with details of the structure and function of the embodiments, the present disclosure is illustrative only, and variation may be made in detail, especially in the matters of shape, size, and arrangement of parts within the principles of the embodiments to the full extent indicated by the broad general meaning of the terms in which the appended claims are expressed.

What is claimed is:

1. A portable electronic device, comprising:
a combination button; and
a gravity sensor,
wherein the combination button is pressed for a first predetermined time, the gravity sensor detects a gravity variation of the portable electronic device; when the combination button is pressed within a second predetermined time, and when the gravity sensor detects no gravity variation, the combination button shuts down the portable electronic device; when the gravity sensor detects a gravity variation, the combination button increases or decreases a volume of the portable electronic device according to the gravity variation.

2. The portable electronic device of claim 1, further comprising a first end and a second end opposite to the first end, a display, and an earphone, wherein the display and the earphone are arranged on a front surface of the portable electronic device, the earphone is arranged on the first end, the gravity sensor is arranged on the second end, the combination button is arranged on a sidewall and on the first end.

3. The portable electronic device of claim 2, wherein when the second end of the portable electronic device rotates counter to a gravity direction, the gravity sensor detects a gravity increment and a displacement of the second end, the portable electronic device increases the volume and adjusts the volume increment according to the displacement.

4. The portable electronic device of claim 2, wherein when the second end of the portable electronic device rotates along a gravity direction, the gravity sensor detects a gravity decrement and a displacement of the second end, the portable electronic device decreases the volume and adjusts the volume decrement according to the displacement.

5. The portable electronic device of claim 1, wherein the combination button is released to finish the power switch function or the volume adjustment.

6. The portable electronic device of claim 1, wherein when the portable electronic device is in a state of power off, the combination button is pressed to startup the portable electronic device.

7. The portable electronic device of claim 2, wherein position of the earphone is kept close to an ear of a user, the position of the earphone acts a first fixed point, the second end is rotated relatively to the fixed point for adjusting volume.

8. The portable electronic device of claim 2, wherein when the portable electronic device is held by a user within a distance from the user, a position of the user pressing the combination button acts a second fixed point, the second end is rotated relatively to the fixed point for adjusting the volume.

9. An operating method of a portable electronic device, comprising:
pressing a combination button of the for portable electronic device a first predetermined time;
determining a gravity variation of the portable electronic device using a gravity sensor of the portable electronic device;
if the gravity variation is within a first range, shutting down the portable electronic device;
if the gravity variation is within a second range, increasing a volume of the portable electronic device according to the gravity variation;
if the gravity variation is within a third range, decreasing the volume of the portable electronic device according to the gravity variation.

10. The operating method of claim 9, wherein when the gravity variation is zero, the gravity variation is within the first range; when the gravity variation is a gravity increment, the gravity variation is within the second range; when the gravity variation is a gravity decrement, the gravity variation is within the third range.

11. The operating method of claim 10, wherein when an end of the portable electronic device corresponds to the gravity sensor rotates counter to a gravity direction, the gravity sensor detects a gravity increment and a displacement of the electronic device, thereby increasing the volume and adjusting the volume increment according to the displacement.

12. The operating method of claim 10, wherein when an end of the portable electronic device corresponds to the gravity sensor rotates along a gravity direction, the gravity sensor detects a gravity decrement and a displacement of the electronic device, thereby decreasing the volume and adjusting the volume decrement according to the displacement.

13. The operating method of claim 9, further comprising releasing the combination button to finish the power switch function or the volume adjustment.

14. The operating method of claim 9, wherein when the portable electronic device is in a state of power off, pressing the combination button to startup the portable electronic device.
